(19) United States
(12) Patent Application Publication
(10) Pub. No.: US 2003/0143835 A1
(43) Pub. Date: Jul. 31, 2003

(54) Dual damascene process for improving planarization of an inter-metal dielectric layer

(76) Inventor: Shyh-Dar Lee, Hsinchu Hsien (TW)

Correspondence Address: Merchant & Gould P.C., P. O. Box 2903, Minneapolis, MN, 55402-0903, US

(21) Appl. No.: 10/155,557

(22) Filed: May 24, 2002

(30) Foreign Application Priority Data
Jan. 29, 2002 (TW) 91101446

(51) Int. Cl. H01L 21/4763

(52) U.S. Cl. 438/625

(57) ABSTRACT

A dual damascene process for improving planarization of an inter-metal dielectric (IMD) layer. A removable protective layer is provided between a hard mask layer and an IMD layer to prevent the top of the IMD layer from erosion by dry etching during the formation of a dual damascene opening. After using an organic solution to remove the removable protective layer, the top of the IMD layer becomes a planarized surface.

### BACKGROUND OF THE INVENTION

1. Field of the Invention

The present invention relates to a dual damascene process and, more particularly, to a method of improving the planarization of an inter-metal dielectric layer in a dual damascene structure.

2. Description of the Related Art

In conventional multilevel interconnection processing, a metal layer is patterned to serve as metal wires using a dry etching and then a dielectric layer is deposited to fill gaps between the metal wires. In dual damascene processing, a dielectric layer is etched to provide vias and trenches to serve as a circuit pattern and then a metal layer is deposited to fill the vias and trenches to serve as metal wires. By comparison, the step of etching the metal layer is not required in the dual damascene process. Currently, Cu wires are employed to substitute the traditional Al wires to provide lower resistance. Since dry etching the Cu layer is difficult to control in conventional multilevel interconnection, the dual damascene process has become more and more important when forming the Cu wires.

FIGS. 1A to 1D are sectional diagrams showing a Cu dual damascene process according to prior art. First, as shown in FIG. 1A, a plurality of metal wiring layers 11 are completed on a substrate 10, and then a sealing layer 12, an inter-metal dielectric (IMD) layer 13 and a hard mask layer 15 are sequentially deposited on the entire surface of the substrate 10. Next, using photolithography and dry etching, the hard mask layer 15 is patterned to form a plurality of first openings 16 positioned corresponding to the metal wiring layers 11, respectively. The diameter of the first opening 16 is employed to define the diameter of a predetermined trench of a dual damascene opening.

As shown in FIG. 1B, using photolithography and dry etching, the exposed regions of the IMD layer 13 are patterned to form a plurality of second openings 18 under the first openings 16, respectively. The depth of the second opening 18 is controlled to reach more than half of the thickness of the IMD layer 13. The diameter of the second opening 18 is smaller than that of the first opening 16, and is employed to define the diameter of a predetermined contact via of a dual damascene opening. As shown in FIG. 1C, using dry etching with the hard mask layer 15, the IMD layer 13 and the sealing layer 12 under each first opening 16 are etched to form a trench 17 and a contact via 19, serving as a dual damascene opening. The contact vias 19 expose the metal wiring layers 11, respectively. During dry etching, the hard mask layer 15 is completely removed by reactive ion plasma, thus the exposed top of the IMD layer 13 is slightly eroded to form a rough surface. Next, as shown in FIG. 1D, a barrier layer 9 of Ta/TaN is deposited on the entire surface of the substrate 10. However, since the step coverage problem is caused by the concave and convex profile, the barrier layer 9 deposited on the exposed top of the IMD layer 13 becomes discontinuous. Accordingly, when the subsequent electro-chemical deposition uses the barrier layer 9 as a plating electrode to deposit a Cu layer, the Cu layer cannot completely fill the dual damascene opening. This decreases the reliability of the Cu dual damascene structure.

### SUMMARY OF THE INVENTION

The present invention is a dual damascene process for improving planarization of an inter-metal dielectric (IMD) layer. A dual damascene process uses a removable protective layer between a hard mask layer and an IMD layer to prevent the top of the IMD layer from erosion by dry etching during the formation of a dual damascene opening. After use of an organic solution to remove the removable protective layer, the top of the IMD layer becomes a planarized surface.

In the preferred embodiment, a dual damascene process comprises steps of: providing a semiconductor substrate with a metal wiring layer patterned thereon; successively depositing a sealing layer, an IMD layer, a removable protective layer and a hard mask layer on the semiconductor substrate; patterning the hard mask layer and the removable protective layer to form a first opening positioned corresponding to the metal wiring layer; patterning the IMD layer to form a second opening within the first opening, in which the second opening is positioned corresponding to the metal wiring layer; patterning the IMD layer and the sealing layer to form a trench and a contact via within the first opening and the second opening and removing the hard mask layer, in which the trench and the contact via serve a dual damascene opening and the contact via exposes the metal wiring layer; removing the removable protective layer to expose the top of the IMD layer; depositing a barrier layer on the entire surface of the semiconductor substrate; and forming a metal layer to fill the dual damascene opening and electrically connect the metal wiring layer.

Preferably, the IMD layer is an organic material with a dielectric constant less than 3. The removable protective layer is an organic anti-reflective material, an organic low-k dielectric material, or a polymer/oligomer material that is soluble in an organic solution. The hard mask layer is SiC, SiN or SOG. The sealing layer is SiN. The barrier layer is Ta/TaN. The removable protective layer is removed using an organic solution of hexamethylene, acetone, or isopropane.

Accordingly, it is a principal object of the invention to improve the planarization of the IMD layer without a concave and convex profile.

It is another object of the invention to use an organic solution to remove the removable protective layer without damage to the IMD layer, and the process cost is low.

Yet another object of the invention is to use the removable protective layer to increase the adhesion between the IMD layer and the hard mask layer.

These and other objects of the present invention will become readily apparent upon further review of the following specification and drawings.

### BRIEF DESCRIPTION OF THE DRAWINGS

FIGS. A to 1D are sectional diagrams showing a Cu dual damascene process according to prior art.

FIGS. 2 to 7 are sectional diagrams showing a dual damascene process according to the present invention.

Similar reference characters denote corresponding features consistently throughout the attached drawings.

### DETAILED DESCRIPTION OF THE PREFERRED EMBODIMENTS

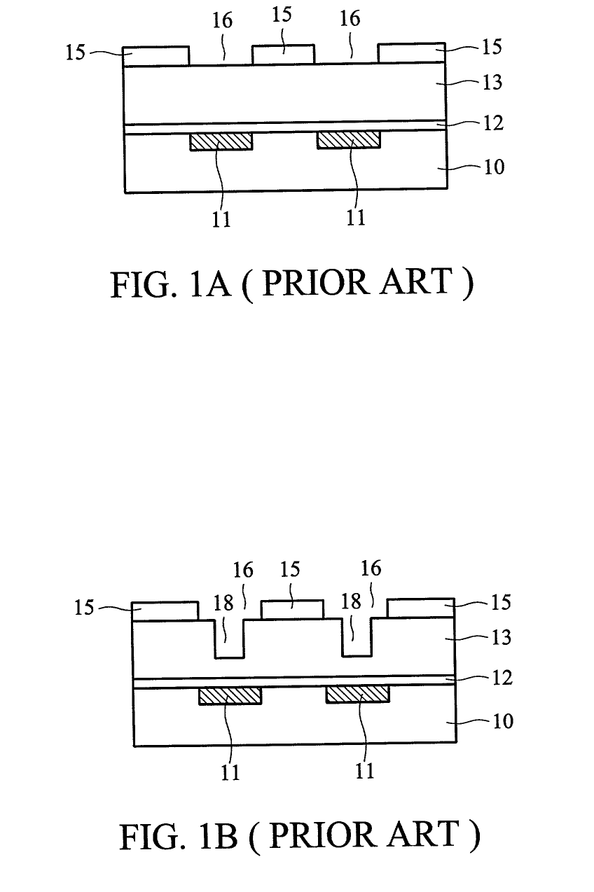

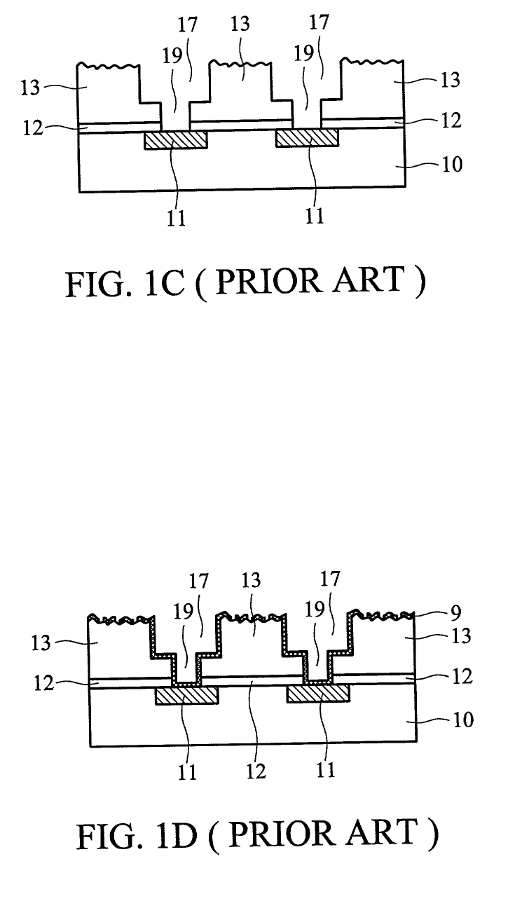

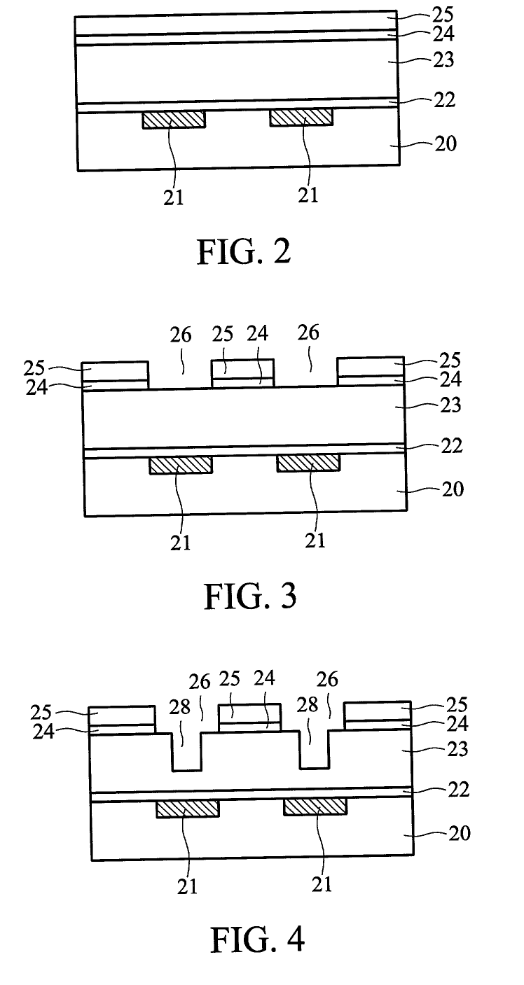

FIGS. 2 to 7 are sectional diagrams showing a dual damascene process according to the present invention. First, as shown in FIG. 2, a semiconductor substrate 20 is provided with a plurality of metal wiring layers 21 patterned thereon. Then, a sealing layer 22, an IMD layer 23, a removable protective layer 24, and a hard mask layer 25, are successively deposited on the entire surface of the semiconductor substrate 20. Preferably, the IMD layer 23 of 6000 Å is an organic low-k dielectric material with a dielectric constant less than 3, such as SiLK, FLARE and polyimide. The removable protective layer 24 may be an organic anti-reflective material (such as ARC and materials used in photolithography), an organic low-k dielectric material (such as SiLK, FLARE and polyimide), or a polymer/oligomer material soluble in an organic solution, such as hexamethylene, acetone and isopropane. The hard mask layer 25 may be SiC, SiN or SOG. The sealing layer 22 is SiN of 300 Å.

As shown in FIG. 3, using photolithography and dry etching, the hard mask layer 25 and the removable protective layer 24 are patterned to form a plurality of first openings 26 positioned corresponding to the metal wiring layers 21, respectively. The diameter of the first opening 26 is employed to define the diameter of a predetermined trench of a dual damascene opening.

As shown in FIG. 4, using photolithography and dry etching, the IMD layer 23 is etched to form a plurality of second openings 28 under the first openings 26, respectively. The depth of the second opening 28 is 2500 Å. The diameter of the second opening 28 is smaller than that of the first opening 26, and employed to define the diameter of a predetermined contact via of a dual damascene opening.

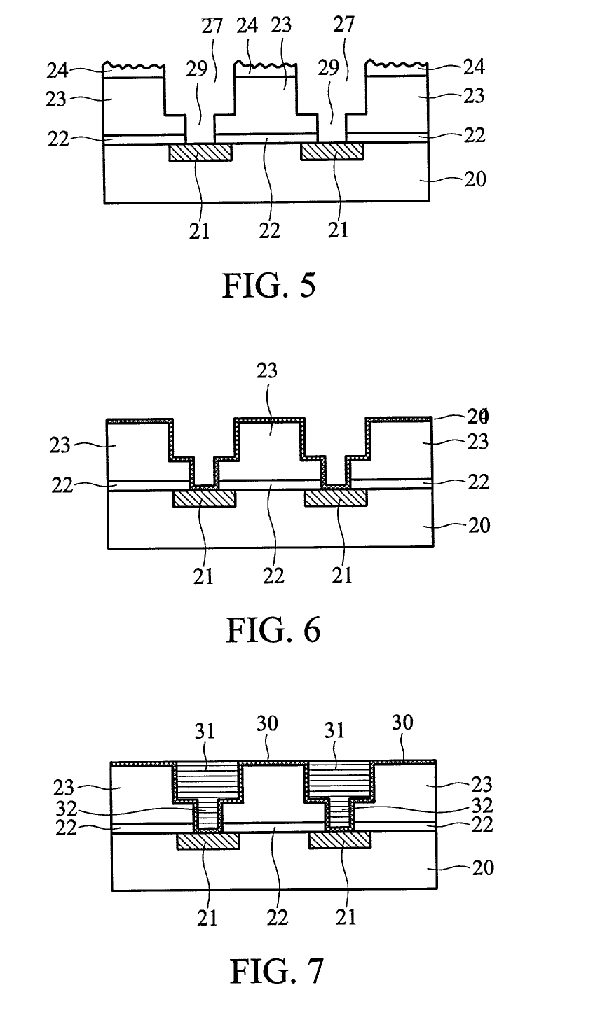

As shown in FIG. 5, using dry etching with the hard mask layer 15, the IMD layer 23 and the sealing layer 22 under each first opening 26 are etched to form a trench 27 of 2500 Ådepth and a contact via 29 of 3500 Ådepth. The trench 27 is over the contact via 29, and the contact via 29 exposes the metal wiring layer 21, thus the trench 27 and the contact via 29 serve as a dual damascene opening. Also, during dry etching, the hard mask layer 25 is completely removed by reactive ion plasma, and the exposed surface of the removable protective layer 24 is slightly eroded to form a rough surface. This remaining removable protective layer 24 protects the top of the IMD layer 23 from a concave/convex profile caused by dry etching.

As shown in FIG. 6, an organic solution, such as hexamethylene, acetone and isopropane is used to remove the removable protective layer 24 to expose the top of the IMD layer 23. Thus, the exposed top of the IMD layer 23 has a planarized profile. Thereafter, a barrier layer 30 of Ta/TaN is deposited on the entire surface of the substrate 20. Since the planarization of the IMD layer 23 is improved without a concave and convex profile, the barrier layer 30 deposited on the exposed top of the IMD layer 23 becomes continuous.

As shown in FIG. 7, using electric-chemical deposition with the barrier layer 30 as a plating electrode, a metal layer is deposited to fill the trench 27 and the contact via 29. Therefore, the metal layer within the trench 27 serves as a metal wire 31, and the metal layer within the contact via 29 serves as a contact plug 32 for electrically connecting the metal wiring layer 21. Preferably, Cu is used to form the metal layer.

Compared with prior art, the present invention provides the removable protective layer 24 between the hard mask layer 25 and the IMD layer 23 to prevent the IMD layer 23 from erosion during dry etching. Thus, the planarization of the IMD layer 23 is improved without a concave and convex profile, and the barrier layer 30 deposited on the exposed top of the IMD layer 23 becomes continuous. Also, the present invention uses the organic solution to remove the removable protective layer 24 without damage to the IMD layer 23, and the process cost is low. Furthermore, the removable protective layer 24 can increase the adhesion between the IMD layer 23 and the hard mask layer 25.

It is to be understood that the present invention is not limited to the embodiments described above, but encompasses any and all embodiments within the scope of the following claims.

What is claimed is:

1. A dual damascene process for improving planarization of an inter-metal dielectric (IMD) layer, comprising steps of:
providing a semiconductor substrate with a metal wiring layer patterned thereon;
successively depositing a sealing layer, an IMD layer, a removable protective layer and a hard mask layer on the semiconductor substrate; patterning the hard mask layer and the removable protective layer to form a first opening positioned corresponding to the metal wiring layer;
patterning the IMD layer to form a second opening within the first opening, in which the second opening is positioned corresponding to the metal wiring layer;
patterning the IMD layer and the sealing layer to form a trench and a contact via within the first opening and the second opening and removing the hard mask layer, in which the trench and the contact via serve a dual damascene opening and the contact via exposes the metal wiring layer; and
removing the removable protective layer to expose the top of the IMD layer;
depositing a barrier layer on the entire surface of the semiconductor substrate; and
forming a metal layer to fill the dual damascene opening and electrically connect the metal wiring layer.

2. The dual damascene process for improving planarization of an inter-metal dielectric (IMD) layer according to claim 1, wherein the IMD layer is an organic material with a dielectric constant less than 3.

3. The dual damascene process for improving planarization of an inter-metal dielectric (IMD) layer according to claim 1, wherein the removable protective layer is an organic anti-reflective material, an organic low-k dielectric material, or a polymer/oligomer material that is soluble in an organic solution.

4. The dual damascene process for improving planarization of an inter-metal dielectric (IMD) layer according to claim 1, wherein the hard mask layer is SiC, SiN or SOG.

5. The dual damascene process for improving planarization of an inter-metal dielectric (IMD) layer according to claim 1, wherein the sealing layer is SiN.

6. The dual damascene process for improving planarization of an inter-metal dielectric (IMD) layer according to claim 1, wherein the barrier layer is Ta/TaN.

7. The dual damascene process for improving planarization of an inter-metal dielectric (IMD) layer according to claim 1, wherein the diameter of the first opening defines the diameter of the trench.

8. The dual damascene process for improving planarization of an inter-metal dielectric (IMD) layer according to claim 1, wherein the diameter of the second opening defines the diameter of the contact via.

9. The dual damascene process for improving planarization of an inter-metal dielectric (IMD) layer according to claim 1, wherein the removable protective layer is removed using an organic solution selected from hexamethylene, acetone and isopropane.
